(19) United States
(12) Patent Application Publication
(10) Pub. No.: US 2025/0329674 A1
(43) Pub. Date: Oct. 23, 2025

(54) SEMICONDUCTOR PACKAGES HAVING SEMICONDUCTOR CHIPS HAVING REAR STRUCTURE

(71) Applicant: Samsung Electronics Co., Ltd., Suwon-si (KR)

(72) Inventors: Jungmin Ko, Suwon-si (KR); Hyunhee Lee, Suwon-si (KR)

(21) Appl. No.: 19/071,940

(22) Filed: Mar. 6, 2025

(30) Foreign Application Priority Data
Apr. 18, 2024 (KR) 10-2024-0052230
Jun. 19, 2024 (KR) 10-2024-0079598

(51) Int. Cl. H01L 23/00; H01L 25/07

(52) U.S. Cl. CPC H01L 24/06; H01L 24/16; H01L 24/32; H01L 24/73; H01L 25/074; H01L 2224/0603; H01L 2224/06051; H01L 2224/06132; H01L 2224/06515; H01L 2224/16145; H01L 2224/32145; H01L 2224/73204

(57) ABSTRACT

A semiconductor package includes a plurality of chip interconnection terminals between a first semiconductor chip and a second semiconductor chip. The second semiconductor chip includes a test pad region between a first pad region and a second pad region. The first pad region includes a plurality of first front pads, the second pad region includes a plurality of second front pads, and the test pad region includes a test pad. The pads of the plurality of first front pads are spaced apart from each other by a first pitch, and a minimum distance between the plurality of first front pads and the plurality of second front pads is greater than the first pitch. At least a portion of the rear conductive pattern of the first semiconductor chip vertically overlaps the test pad.

### CROSS-REFERENCE TO RELATED APPLICATION(S)

This U.S. non-provisional application claims benefit of priority to Korean Patent Application Nos. 10-2024-0052230 filed on Apr. 18, 2024, and 10-2024-0079598 filed on Jun. 19, 2024, in the Korean Intellectual Property Office, the disclosures of which are incorporated herein by reference in their entireties.

### BACKGROUND

The present inventive concept relates to a semiconductor package including a semiconductor chip having a rear structure.

As demand for high performance, high speed, and/or multifunctionality in semiconductor devices has increased, the degree of integration of semiconductor devices has increased. In manufacturing fine-patterned semiconductor devices in response to the trend toward high integration of semiconductor devices, it is desired to implement patterns with a fine width or a fine distance. In addition, high integration of semiconductor devices mounted on semiconductor packages is desirable.

### SUMMARY

An aspect of the present inventive concept is to provide a semiconductor package including a semiconductor chip having a structure on a rear surface.

According to an aspect of the present inventive concept, a semiconductor package includes: a first semiconductor chip including a substrate having a front side and a back side opposite each other, a rear protective layer on the back side, a plurality of rear pads on the rear protective layer, and a rear conductive pattern between two rear pads of the plurality of rear pads; a second semiconductor chip on the first semiconductor chip and including a first pad region, a second pad region, and a test pad region between the first pad region and the second pad region; a plurality of chip interconnection terminals between the first semiconductor chip and the second semiconductor chip, in which each chip interconnection terminal of the plurality of chip interconnection terminals is connected to a respective rear pad of the plurality of rear pads of the first semiconductor chip; and an adhesive layer surrounding the plurality of chip interconnection terminals between the first semiconductor chip and the second semiconductor chip, wherein the first pad region includes a plurality of first front pads, the second pad region includes a plurality of second front pads, and the test pad region includes a test pad, the pads of the plurality of first front pads are spaced apart from each other at a first pitch, a minimum distance between the plurality of first front pads and the plurality of second front pads is greater than the first pitch, and at least a portion of the rear conductive pattern vertically overlaps the test pad.

According to an aspect of the present inventive concept, a semiconductor package includes: a first semiconductor chip including a substrate having a front side and a back side opposite each other, a rear protective layer on the back side of the substrate, a plurality of rear pads on the rear protective layer, and a rear conductive pattern between two rear pads of the plurality of rear pads; a second semiconductor chip on the first semiconductor chip and including a plurality of front pads electrically connected to the plurality of rear pads and a test pad between two front pads of the plurality of front pads; a plurality of chip interconnection terminals each chip interconnection terminal being between a respective rear pad of the plurality of rear pads of the first semiconductor chip, and a respective front pad of the plurality of front pads of the second semiconductor chip; and an adhesive layer surrounding the plurality of chip interconnection terminals between the first semiconductor chip and the second semiconductor chip, the plurality of chip interconnection terminals includes a first chip interconnection terminal, a second chip interconnection terminal, and a third chip interconnection terminal spaced apart from each other in a first horizontal direction, a first center of the first chip interconnection terminal and a second center of the second chip interconnection terminal are spaced apart from each other by a first distance in the first horizontal direction and the second center of the second chip interconnection terminal is spaced apart from a third center of the third chip interconnection terminal by a second distance, greater than the first distance, in the first horizontal direction, the test pad is between the second chip interconnection terminal and the third chip interconnection terminal, and at least a portion of the rear conductive pattern vertically overlaps the test pad.

According to an aspect of the present inventive concept, a semiconductor package includes: a plurality of semiconductor chips stacked in a vertical direction; a plurality of bump terminals electrically connecting the plurality of semiconductor chips between the plurality of semiconductor chips; a plurality of adhesive layers surrounding the plurality of bump terminals between the plurality of semiconductor chips; and an encapsulant covering the plurality of semiconductor chips and the plurality of adhesive layers, wherein the plurality of semiconductor chips include: a first semiconductor chip including a substrate having a front side and a back side opposite each other, a rear protective layer on the back side of the substrate, a plurality of rear pads on the rear protective layer, and a rear conductive pattern between two rear pads of the plurality of rear pads; and a second semiconductor chip on the first semiconductor chip and including a first pad region, a second pad region, and a test pad region between the first pad region and the second pad region; wherein the first pad region includes a plurality of first front pads, the second pad region includes a plurality of second front pads, and the test pad region includes a test pad, the pads of the plurality of first front pads are spaced apart from each other at a first pitch, a minimum distance between the plurality of first front pads and the plurality of second front pads is greater than the first pitch, and at least a portion of the rear conductive pattern vertically overlaps the test pad.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a vertical cross-sectional view of a semiconductor package according to example embodiments;

FIG. 2 is a plan view of a semiconductor chip illustrated in FIG. 1;

FIG. 3 is an enlarged view of a portion of the semiconductor chip illustrated in FIG. 2;

FIG. 4 is a plan view of the semiconductor chip illustrated in FIG. 1;

FIG. 5 is a vertical cross-sectional view of the semiconductor chip illustrated in FIG. 3 taken along line I-I′;

FIGS. 6 to 9 are plan views of semiconductor chips according to example embodiments;

FIGS. 10 to 12 are vertical cross-sectional views of semiconductor packages according to example embodiments;

FIGS. 13A to 13F are cross-sectional views illustrating a major process of a method of manufacturing a semiconductor package according to example embodiments; and

FIG. 14 is a vertical cross-sectional view of a semiconductor package according to example embodiments.

### DETAILED DESCRIPTION

Hereinafter, example embodiments of the present inventive concept will be described with reference to the accompanying drawings. The invention may, however, be embodied in many different forms and should not be construed as limited to the example embodiments set forth herein.

Terms such as “same,” “same as,” “equal,” “equal to,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes.

It will be understood that, although the terms “first”, “second”, “third”, etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim to distinguish different claimed elements from each other.

Spatially relative terms, such as “below,” “lower,” “above,” “upper,” “top,” “front,” “rear,” and the like, may be used herein for ease of description to describe positional relationships, such as illustrated in the figures, for example. It will be understood that the spatially relative terms encompass different orientations of the device in addition to the orientation depicted in the figures.

It will be understood that the terms “include”, “includes,” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component.

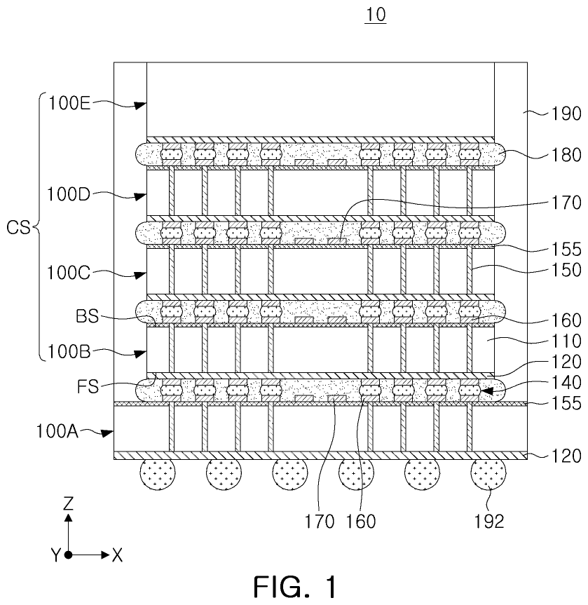

FIG. 1 is a vertical cross-sectional view of a semiconductor package according to example embodiments.

Referring to FIG. 1, a semiconductor package 10 according to an example embodiment of the present inventive concept may include a first semiconductor chip 100A, a chip structure CS, an adhesive layer 180, an encapsulant 190, and a connection terminal 192.

The chip structure CS may be disposed on the first semiconductor chip 100A. The chip structure CS may be a chip stack that may include a plurality of semiconductor chips, for example, a second semiconductor chip 100B, a third semiconductor chip 100C, a fourth semiconductor chip 100D, and a fifth semiconductor chip 100E. The first to fifth semiconductor chips 100A, 100B, 100C, 100D, and 100E may have similar structures. In FIG. 1, widths of the second semiconductor chip 100B, third semiconductor chip 100C, fourth semiconductor chip 100D, and fifth semiconductor chip 100E in a horizontal direction (for example, an X-direction) are the same and a horizontal width of the first semiconductor chip 100A is illustrated as being greater than the horizontal width of the second semiconductor chip 100B but is not limited thereto. In an example embodiment, the horizontal width of the first semiconductor chip 100A may be equal to the horizontal widths of the second semiconductor chip 100B, the third semiconductor chip 100C, the fourth semiconductor chip 100D, and the fifth semiconductor chip 100E.

According to an example embodiment, the chip structure CS may include more or fewer semiconductor chips than those illustrated in the drawing. For example, the chip structure CS may include three or fewer, or five or more, semiconductor chips. According to an example embodiment, a heat dissipation structure may be disposed on top of the chip structure CS. The heat dissipation structure (not shown) may include a material having excellent thermal conductivity, for example, at least one of aluminum (Al), gold (Au), silver (Ag), copper (Cu), iron (Fe), graphite, or graphene, and the like.

In an example embodiment, the first semiconductor chip 100A may be a buffer chip or a control chip including a plurality of logic devices and/or memory devices. The first semiconductor chip 100A may transmit signals from the second to fifth semiconductor chips 100B, 100C, 100D, and 100E stacked on the first semiconductor chip 100A externally and may transmit signals and power from an external source to the second to fifth semiconductor chips 100B, 100C, 100D, and 100E. The second to fifth semiconductor chips 100B, 100C, 100D, and 100E may be memory chips including volatile memory devices, such as DRAM and SRAM, or non-volatile memory devices, such as PRAM, MRAM, FeRAM, or RRAM. The semiconductor package 10 of the present example embodiment may be used in high bandwidth memory (HBM) products, electro data processing (EDP) products, etc.

The semiconductor package 10 may further include a bump structure 140, (e.g., a chip interconnection terminal or bump terminal), disposed between the plurality of semiconductor chips 100A, 100B, 100C, 100D, and 100E. The bump structures 140 and through-vias 150 may electrically connect the plurality of semiconductor chips 100A, 100B, 100C, 100D, and 100E to each other.

The adhesive layer 180 may be disposed between the plurality of semiconductor chips 100A, 100B, 100C, 100D, and 100E and may surround the bump structures 140. A portion of the adhesive layer 180 may protrude in the horizontal direction from side surfaces of the plurality of semiconductor chips 100A, 100B, 100C, 100D, and 100E.

The encapsulant 190 may be disposed on the first semiconductor chip 100A and may seal at least a portion of each of the second to fifth semiconductor chips 100B, 100C, 100D, and 100E. The encapsulant 190 may be formed to expose an upper surface of the fifth semiconductor chip 100E disposed at the uppermost portion. In an example embodiment, the encapsulant 190 may be formed to cover the upper surface of the fifth semiconductor chip 100E. The encapsulant 190 may include a resin including epoxy or polyimide. For example, the resin may include bisphenol-group epoxy resin, polycyclic aromatic epoxy resin, o-Cresol Novolac epoxy resin, and biphenyl-group epoxy resin, or naphthalene-group epoxy resin.

The connection terminal 192 may be disposed on a lower surface of a substrate 110 of the first semiconductor chip 100A. The connection terminal 192 may be electrically connected to a circuit layer 120 of the substrate 110 of the first semiconductor chip 100A. The connection terminal 192 may be electrically connected to an external device, such as a main board. The connection terminal 192 may include a conductive material and may have a ball, pin, or lead shape. For example, the connection terminal 192 may be an external connection terminal such as a solder ball, for connecting the semiconductor package 10 to an external device.

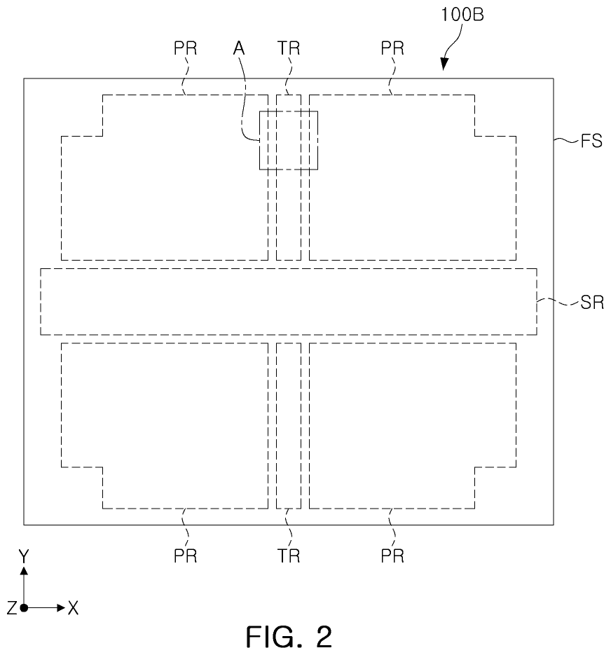

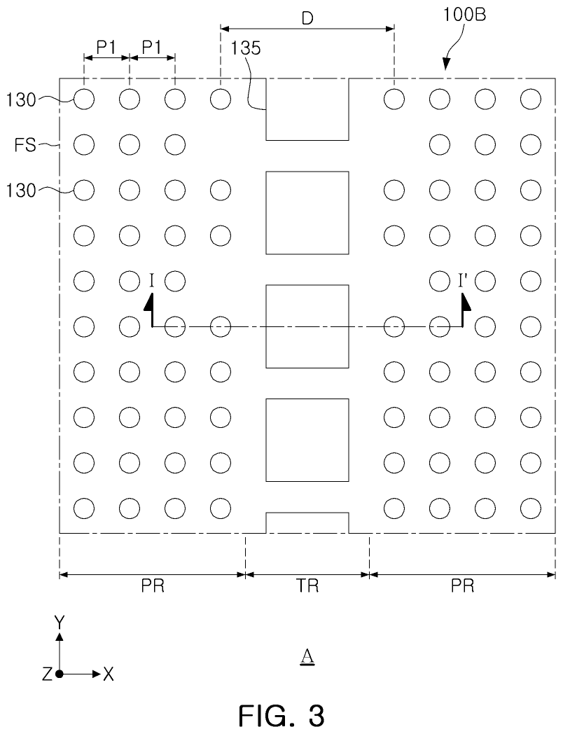

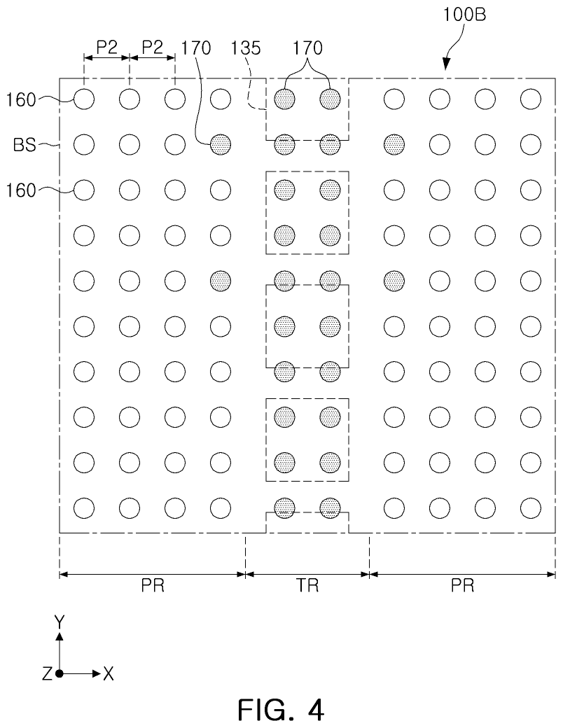

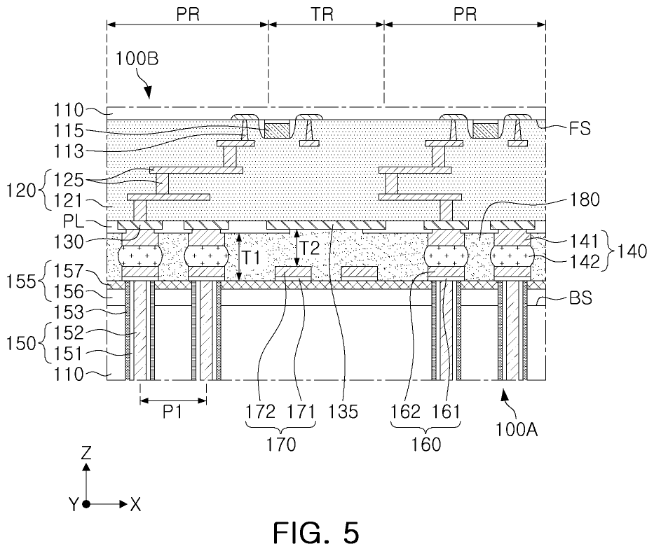

FIG. 2 is a plan view of the semiconductor chip illustrated in FIG. 1. For example, FIG. 2 may be a plan view of a front side FS of the second semiconductor chip 100B viewed from below. FIG. 3 is an enlarged view of a portion of the semiconductor chip illustrated in FIG. 2. For example, FIG. 3 may correspond to region A illustrated in FIG. 2. FIG. 4 is a plan view of the semiconductor chip illustrated in FIG. 1. For example, FIG. 4 may be a plan view of a back side BS of the first semiconductor chip 100A viewed from above. For convenience of description, the location of a test pad 135 of the second semiconductor chip 100B is illustrated by the dotted line in FIG. 4. FIG. 5 is a vertical cross-sectional view of the semiconductor chip illustrated in FIG. 3 taken along line I-I′.

Referring further to FIGS. 2 to 5, the plurality of semiconductor chips 100A, 100B, 100C, 100D, and 100E each may include the substrate 110, the circuit layer 120, a front pad 130, a test pad 135, the through-via 150, a rear protective layer 155, a rear pad 160, and a rear structure 170, such as a rear conductive pattern. Items described in the singular (e.g., a pad) may be provided in plural, as will be evident from the figures and other descriptions within the specification. According to an example embodiment, the semiconductor chip at the top of the chip structure CS, for example, the fifth semiconductor chip 100E, may not include the through-via 150, the rear protective layer 155, the rear pad 160, and the rear structure 170. First pad region PR may include first front pads from among front pads 130, and second pad region PR may include second front pads from among front pads 130. The test pad 135 may be included in a test region TR.

The substrate 110 may be a semiconductor wafer substrate having a front side FS and a back side BS opposite to each other. For example, the substrate 110 may be a semiconductor wafer including a semiconductor element, such as silicon, germanium or a compound semiconductor, such as silicon carbide (SiC), gallium arsenide (GaAs), indium arsenide (InAs), and indium phosphide (InP). The front side FS may be an active surface having an active region doped with impurities, and the back side BS may be an inactive surface located opposite to the front side FS.

The circuit layer 120 is disposed on the front side FS of the substrate 110 and may include an interconnection structure 125 connected to the active region and an interlayer insulating layer 121 surrounding the interconnection structure 125. The interlayer insulating layer 121 is formed of flowable oxide (FOX), tonen silazen (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide, or combinations thereof. At least a portion of the interlayer insulating layer 121 surrounding the interconnection structure 125 may be formed of a low-k dielectric layer. The interlayer insulating layer 121 may be formed using a chemical vapor deposition (CVD) process, a flowable CVD process, or a spin coating process. The interconnection structure 125 may include a multilayer structure including a via and an interconnection pattern formed of, for example, aluminum (Al), gold (Au), cobalt (Co), copper (Cu), nickel (Ni), lead (Pb), tantalum (Ta), tellurium (Te), titanium (Ti), tungsten (W), or combinations thereof. A barrier film (not shown) including titanium (Ti), titanium nitride (TiN), tantalum (Ta), or tantalum nitride (TaN) may be disposed between the interconnection structure 125 and the interlayer insulating layer 121. Individual devices 115 constituting an integrated circuit may be disposed on the front side FS of the substrate 110. In this case, the interconnection structure 125 may be electrically connected to the individual devices 115 by an interconnector 113 (e.g., a contact plug). The individual devices 115 may include FETs, such as planar FET or FinFET, memory devices (e.g., memory cells), such as flash memory, DRAM, SRAM, EEPROM, PRAM, MRAM, FeRAM, and RRAM, logic devices, such as AND, OR, NOT, and various active and/or passive devices, such as system LSI, CIS, and MEMS.

The front pad 130 and the test pad 135 may be disposed on the front side FS of the substrate 110. As illustrated in FIGS. 2 and 3, the plurality of semiconductor chips 100A, 100B, 100C, 100D, and 100E may each include a pad region PR, a pad region SR, and a test pad region TR. The pad region SR may extend in the X-direction, and four pad regions PR may be spaced apart from each other in the X and Y-directions. However, the arrangement structures of the pad region PR, pad region SR, and test pad region TR are examples and are not limited thereto.

Front pads 130 may be disposed in the pad region PR and the pad region SR. For example, front pads 130 used to transmit a power voltage and a ground voltage may be disposed in the pad region PR. Front pads 130 that may provide a path for transmitting/receiving data signals, etc. may be disposed in the pad region SR. The front pads 130 may be electrically connected to the interconnection structure 125 of the circuit layer 120. In an example embodiment, at least one of the front pads 130 disposed in the pad region PR may be a dummy pad not electrically connected to the interconnection structure 125. The front pads 130 are illustrated as being circular in plan view but are not limited thereto. In example embodiments, the front pads 130 may have an oval, square, or other shape.

The test pad region TR may be disposed in the center of the front side FS of the substrate 110. For example, the test pad region TR may be disposed between the pad regions PR spaced apart from each other in the X-direction and may extend in the Y-direction. According to example embodiments as shown for example in FIG. 5, the test pad region TR may be disposed between a first pad region PR on one side in the X-direction and a second pad region PR on an opposite side in the X-direction. The first pad region includes a plurality of first front pads within the X and Y-coordinates of the first pad region, and the second pad region includes a plurality of second front pads within the X and Y-coordinates of the second pad region, and the test pad region includes a test pad within the X and Y-coordinates of the test region.

The test pads 135 may be arranged in the test pad region TR in the Y-direction. The test pads 135 may be used to inspect defects in the plurality of semiconductor chips 100A, 100B, 100C, 100D, and 100E, and may be electrically connected to the interconnection structure 125 of the circuit layer 120. The test pads 135 are illustrated as being square in plan view but are not limited thereto. In example embodiments, the test pads 135 may have a circular, oval, etc. shape. In an example embodiment, a horizontal width of the test pad 135 may be greater than a horizontal width of the front pad 130. As illustrated in FIG. 5, the test pad 135 may be disposed at the same vertical level as that of the front pad 130.

The front pads 130 may be arranged to be spaced apart from each other at a first pitch P1. For example, the pads of the plurality of first front pads 130 within a first pad region are spaced apart from each other at a first pitch. Here, the pitch refers to a horizontal distance between the centers of the front pads 130. The minimum distance between the front pads 130 disposed in different pad regions PR may be greater than the first pitch P1. For example, as illustrated in FIGS. 3 and 5, a distance D between two front pads 130 on opposite sides of and adjacent to the test pad 135 may be greater than the first pitch P1. In example embodiments, a minimum distance between the plurality of first front pads 130 and the plurality of second front pads 130 in the second pad region, is greater than the first pitch P1.

The front pads 130 and the test pads 135 may include a conductive material, for example, at least one of aluminum (Al), gold (Au), cobalt (Co), copper (Cu), nickel (Ni), lead (Pb), tantalum (Ta), tellurium (Te), titanium (Ti), or tungsten (W), or combinations thereof. A barrier film (not shown) including titanium (Ti), titanium nitride (TiN), tantalum (Ta), or tantalum nitride (TaN) may be disposed on at least one surface of the front pads 130 and the test pads 135.

As illustrated in FIG. 5, the plurality of semiconductor chips 100A, 100B, 100C, 100D, and 100E may each further include a front protective layer PL covering the front pad 130 and the test pad 135. The front protective layer PL may cover the circuit layer 120 and partially expose the front pad 130 and the test pad 135.

The through-via 150 may extend vertically from the front side FS to the back side BS of the substrate 110 and may be electrically connected to at least one of the rear pads 160. The through-via 150 may be a conductive via electrically connected to the interconnection structure 125 of the circuit layer 120, for example, a signal line, a power line, and a ground line. In an example embodiment, the rear structure 170 may be spaced apart from the through-vias 150. For example, the rear structure 170 may not vertically overlap the through-vias 150 and may not be electrically connected to the through-vias 150. In some example embodiments, some of the through-vias 150 may vertically overlap the rear structure 170, which may be a rear surface conductive structure, disposed at a rear surface of a respective semiconductor chip.

The through-vias 150 may include a via plug 152 and a barrier layer 151 surrounding a side surface of the via plug 152. The via plug 152 may include, for example, at least one of tungsten (W), titanium (Ti), aluminum (Al), or copper (Cu) and may be formed through a plating process, a PVD process, or a CVD process. The barrier layer 151 may include titanium (Ti), titanium nitride (TiN), tantalum (Ta), or tantalum nitride (TaN) and may be formed through a plating process, a PVD process, or a CVD process.

In addition, each of the plurality of semiconductor chips 100A, 100B, 100C, 100D, and 100E may further include a side insulating film 153 extending along a partial side surface of the through-vias 150. The side insulating film 153 may electrically separate the via plug 152 from the substrate 110. The side insulating film 153 may include an insulating material (e.g., high aspect ratio process (HARP) oxide), such as silicon oxide, silicon nitride, and/or silicon oxynitride and may be formed through a PVD process or a CVD process.

The rear protective layer 155 may be disposed on the back side BS of the substrate 110 and may include an insulating material. The rear protective layer 155 may include, for example, at least one of silicon oxide, silicon nitride, silicon carbide, silicon oxynitride, or silicon carbonitride, etc. According to an example embodiment, the rear protective layer 155 may include a plurality of protective layers. For example, the rear protective layer 155 may include a first protective layer 156 and a second protective layer 172 including different materials. The first protective layer 156 may include silicon oxide, and the second protective layer 157 may include silicon nitride, but are not limited thereto. According to an example embodiment, the rear protective layer 155 may be a single layer formed of silicon oxide. The rear protective layer 155 may protect the back side BS of the substrate 110 and electrically insulate the rear pads 160 and the substrate 110 from each other. The through-via 150 may pass through the rear protective layer 155. For example, an upper surface of the rear protective layer 155 may be coplanar with an upper surface of the through-via 150.

The rear pad 160 and the rear structure 170 may be disposed on the back side BS of the substrate 110. For example, the rear pad 160 and the rear structure 170 may be disposed on the upper surface of the rear protective layer 155. The rear pads 160 may be disposed in the pad region PR and the pad region SR. Each of the rear pads 160 may be electrically connected to the corresponding front pad 130 by the bump structure 140. For example, the rear pads 160 may vertically overlap the corresponding front pads 130, respectively. For example, the rear pads 160 may be arranged at the same pitch as the front pads 130. For example, the rear pads 160 and the front pads 130 may be arranged at the first pitch P1. The rear pads 160 may be electrically connected to the corresponding through-vias 150, respectively. For example, the rear pads 160 may contact the corresponding through-vias 150 and may overlap vertically, respectively.

In example embodiments, each rear pad of the plurality of rear pads 160 is electrically connected to the circuit layer 120, and each rear structure 170 is not electrically connected to the circuit layer 120. The rear structures 170 may be dummy pads or dummy patterns, not electrically connected to other circuit elements (e.g., each rear structure may be electrically floating), or not electrically connected to any active circuit elements, while the rear pads 160 may be connection pads, electrically connected to additional circuit elements such as active circuit elements. For example, each rear structure may be a conductive pattern.

The rear pad 160 may include a seed layer 161 and a metal layer 162 on the seed layer 161. The seed layer 161 may include at least one of titanium (Ti), titanium nitride (TiN), tantalum (Ta), or tantalum nitride (TaN). The metal layer 162 may include at least one of aluminum (Al), gold (Au), cobalt (Co), copper (Cu), nickel (Ni), lead (Pb), tantalum (Ta), tellurium (Te), titanium (Ti) or tungsten (W). For example, the metal layer 162 may include copper (Cu).

The rear structure 170 may be disposed in the test pad region TR. The rear structures 170 may be arranged in the Y-direction within the test pad region TR. For example, the rear structures 170 may vertically overlap the corresponding test pads 135, respectively. By way of example of what is meant by “vertically overlap”, as shown in FIG. 5, the X and Y coordinates of the test pad 135 (or a portion thereof) overlap with the X and Y coordinates of the rear structure 170 (or a portion thereof). In an example embodiment, some of the rear structures 170 may be disposed in the pad region PR, but embodiments are not limited thereto.

In an example embodiment, a horizontal width of the rear structure 170 may be less than a horizontal width of the test pad 135. For example, the rear structures 170 may be arranged in two columns, and when viewed in cross-section, one test pad 135 may vertically overlap two rear structures 170. For example, the horizontal width of the rear structure 170 may be greater than 0.3 times and less than 0.5 times the horizontal width of the test pad 135. In an example embodiment, the rear structures 170 may be arranged at the same pitch as that of the rear pads 160. For example, the rear structures 170 may include a first rear conductive pattern, and further include a second rear conductive pattern spaced apart from the first rear conductive pattern at a second pitch P2, and the second pitch P2 may be equal to the first pitch P1. According to other examples, the second pitch P2 is less than the first pitch P1.

The rear structure 170 may include a seed layer 171 and a metal layer 172 on the seed layer 171. The seed layer 171 may include at least one of titanium (Ti), titanium nitride (TiN), tantalum (Ta), or tantalum nitride (TaN). The metal layer 172 may include at least one of aluminum (Al), gold (Au), cobalt (Co), copper (Cu), nickel (Ni), lead (Pb), tantalum (Ta), tellurium (Te), titanium (Ti) or tungsten (W). For example, the metal layer 172 may include copper (Cu). In an example embodiment, rear structure 170 may include the same material as that of the rear pad 160. For example, the seed layer 171 and the metal layer 172 may include the same material as that of the seed layer 161 and the metal layer 162, respectively.

In an example embodiment, the rear structure 170 may be formed in the same process as the rear pad 160. A size of the rear structure 170 may be equal to a size of the rear pad 160. For example, a horizontal width of the rear structure 170 may be equal to a horizontal width of the rear pad 160. In an example embodiment, a thickness of the rear structure 170 may be equal to a thickness of the rear pad 160.

The rear pad 160 and the rear structure 170 are illustrated in the Figures, including for example, FIGS. 4 and 6-9 as being circular in a plan view, but are not limited thereto. In example embodiments, the rear pad 160 and the rear structure 170 may have an oval, square, or other shape, and need not all have the same shape.

The semiconductor package 10 may further include the bump structures 140 disposed between the plurality of semiconductor chips 100A, 100B, 100C, 100D, and 100E. The bump structures 140 may be in contact with the corresponding front pads 130 and the rear pads 160, respectively, and may be electrically connected to the corresponding front pads 130 and the rear pads 160, respectively. The bump structures 140 may be arranged at the same pitch as that of the rear pads 160. For example, the rear structures 170 may be spaced apart from each other at the first pitch P1. The bump structures 140 may be bump terminals, or chip interconnection terminals, that electrically and physically connect two adjacent semiconductor chips from among the plurality of semiconductor chips 100A, 100B, 100C, 100D, and 100E.

In example embodiments of the present inventive concept, the test pad 135 and the rear structure 170 do not contact the bump structures 140 and may not be electrically connected to the bump structures 140. For example, first and second centers of adjacent first and second bump structures 140 may be spaced apart from each other at the first pitch P1, and the bump structures 140 disposed in different pad regions PR with the test pad 135 interposed therebetween may be spaced apart by the distance D greater than the first pitch P1. In example embodiments, D is a distance between a second center of a second bump structure 140 and a third center of a third bump structure 140, in which the test pad 135 is between the second bump structure 140 and the third bump structure 140.

The bump structure 140 may include a first portion 141 and a second portion 142 below the first portion 141. The first portion 141 may be in contact with the corresponding front pad 130. The first portion 141 may have the shape of a polygonal pillar, such as a cylinder, square pillar, or octagonal pillar and may include, for example, at least one of nickel (Ni), copper (Cu), palladium (Pd), platinum (Pt), or gold (Au), or combinations thereof. The second portion 142 may have a spherical or ball shape and may include, for example, at least one of tin (Sn), indium (In), bismuth (Bi), antimony (Sb), copper (Cu), silver (Ag), zinc (Zn), or lead (Pb), and/or alloys thereof. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, etc., and may form a solder.

The adhesive layers 180 may be disposed between the plurality of semiconductor chips 100A, 100B, 100C, 100D, and 100E and may surround the bump structures 140. The upper surface of the rear structure 170 and the lower surface of the test pad 135 may be in contact with the adhesive layer 180. As illustrated in FIG. 5, the adhesive layer 180 may have a first thickness T1 and a second thickness T2 less than the first thickness T1 between the first semiconductor chip 100A and the second semiconductor chip 100B. For example, the adhesive layer 180 may include a first portion having the first thickness T1 between the rear protective layer 155 and the front protective layer PL and may include a second portion having the second thickness T2 between the rear structure 170 and the test pad 135.

The adhesive layer 180 may be a non-conductive film (NCF) or a molded underfill (MUF) but is not limited thereto. The adhesive layer 180 may include at least one of epoxy resin, silica (SiO₂), or acrylic copolymer, or combinations thereof.

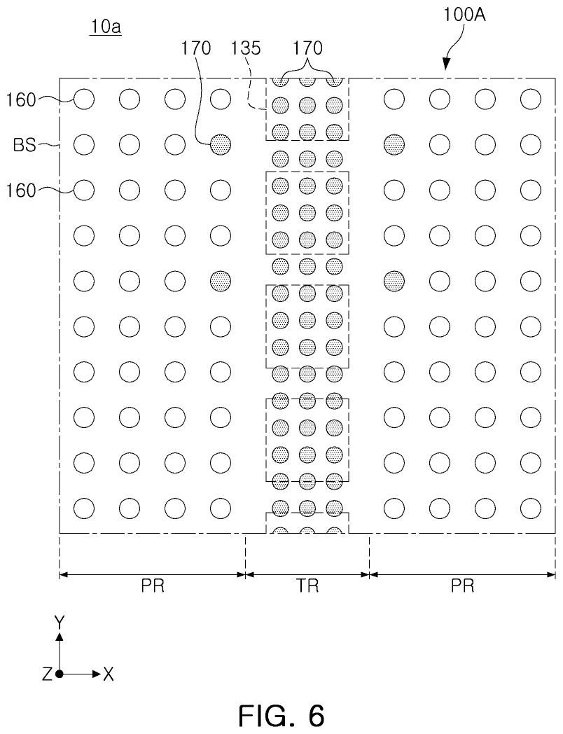

FIGS. 6 to 9 are plan views of semiconductor chips according to example embodiments.

Referring to FIG. 6, the first semiconductor chip 100A of a semiconductor package 10a may include rear structures 170 (e.g., rear dummy pads or conductive patterns) disposed on the back side BS. In an example embodiment, the rear structures 170 may be arranged in three columns. For example, the horizontal width of the rear structure 170 may be greater than 0.2 times and less than 0.3 times than the horizontal width of the test pad 135. In an example embodiment, the rear structures 170 may be arranged at a different pitch than that of the rear pads 160. For example, the rear structures 170 may be spaced apart from each other at a third pitch P3, and the third pitch P3 may be less than the first pitch P1.

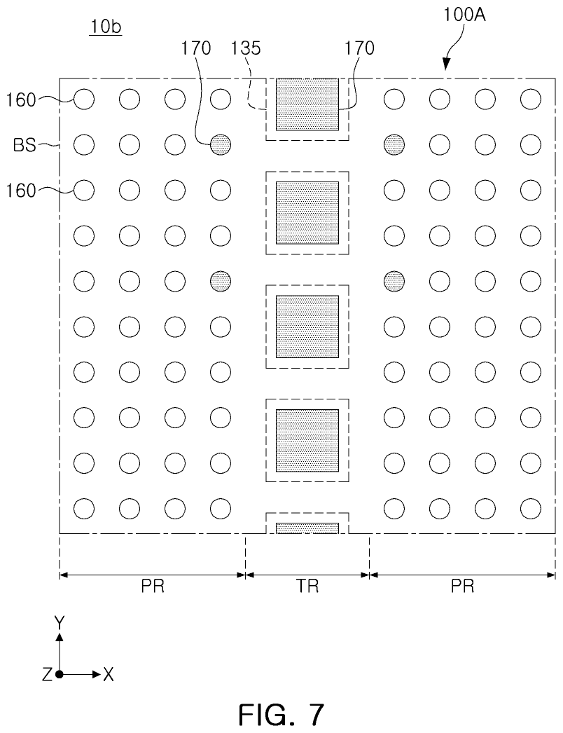

Referring to FIG. 7, the first semiconductor chip 100A of the semiconductor package 10b may include the rear structures 170 (e.g., rear dummy pads or conductive patterns) disposed on the back side BS. In an example embodiment, the rear structures 170 may be arranged in one column, and one test pad 135 may vertically overlap one rear structure 170. In an example embodiment, the horizontal width of the at least one rear structure 170 may be less than the horizontal width of the test pad 135.

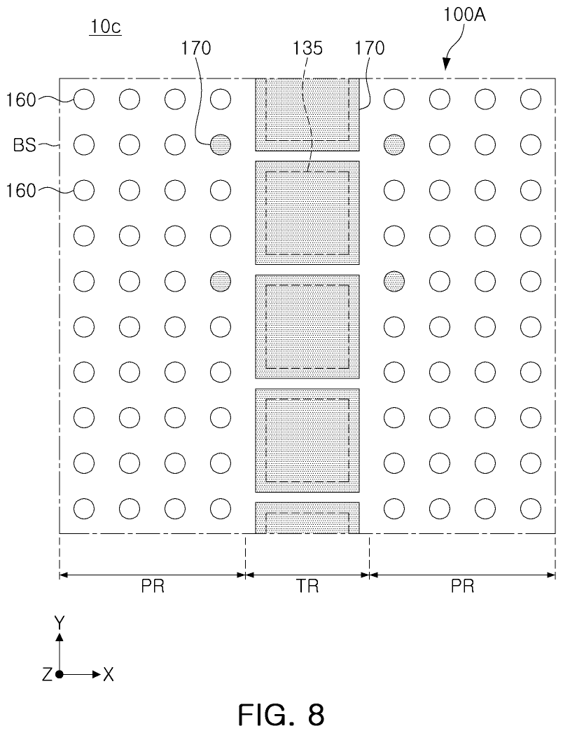

Referring to FIG. 8, the first semiconductor chip 100A of a semiconductor package 10c may include at least one rear structure 170 (e.g., rear dummy pads or conductive patterns) disposed on the back side BS. In an example embodiment, the rear structures 170 may be arranged in one column, and one test pad 135 may vertically overlap one rear structure 170. In an example embodiment, the horizontal width of the rear structures 170 may be greater than the horizontal width of the test pad 135. In an example embodiment, the horizontal width of the rear structures 170 may be equal to the horizontal width of the test pad 135. In the example embodiment of FIGS. 7 and 8, the horizontal width of the rear structures 170 may be 0.8 times to 1.2 times the horizontal width of the test pad 135.

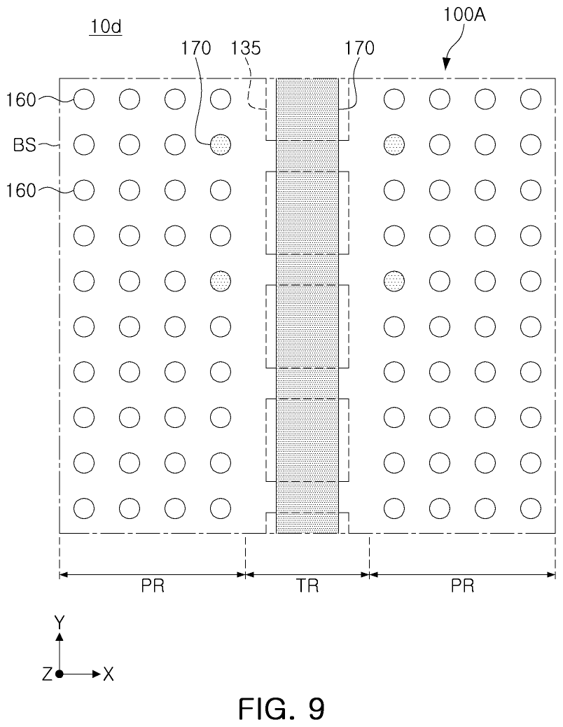

Referring to FIG. 9, the first semiconductor chip 100A of a semiconductor package 10d may include rear structures 170 (e.g., rear dummy pads or conductive patterns) disposed on the back side BS. In an example embodiment, the rear structure 170 may extend in the Y-direction and vertically overlap a plurality of test pads 135. The horizontal width of the rear structures 170 is illustrated as being less than the horizontal width of the test pad 135 but is not limited thereto. In some example embodiments, the horizontal width of rear structures 170 may be greater than or equal to the horizontal width of test pad 135.

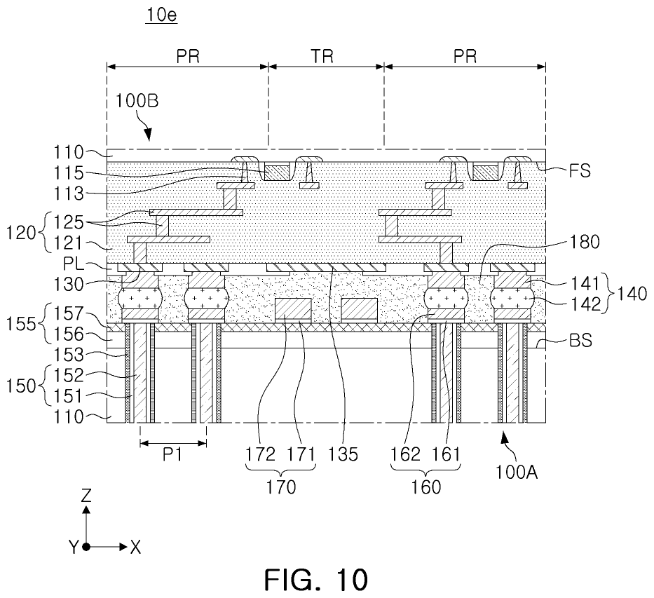

FIGS. 10 to 12 are vertical cross-sectional views of semiconductor packages according to example embodiments.

Referring to FIG. 10, the first semiconductor chip 100A of a semiconductor package 10e may include rear structures 170 disposed on the back side BS. In an example embodiment, the size of the rear structure 170 may be greater than the size of the rear pad 160. For example, the thickness of the rear structure 170 may be greater than the thickness of the rear pad 160. For example, the thickness of the seed layer 171 of the rear structure 170 may be equal to the thickness of the seed layer 161 of the rear pad 160, but the thickness of the metal layer 172 of the rear structure 170 may be greater than the thickness of the metal layer 162 of the rear pad 160. In an example embodiment, the thickness of the rear structure 170 may be 0.5 times to 0.75 times the thickness of the adhesive layer 180. Here, the thickness of the adhesive layer 180 may refer to a vertical distance between the rear protective layer 155 of the first semiconductor chip 100A and the front protective layer PL of the second semiconductor chip 100B.

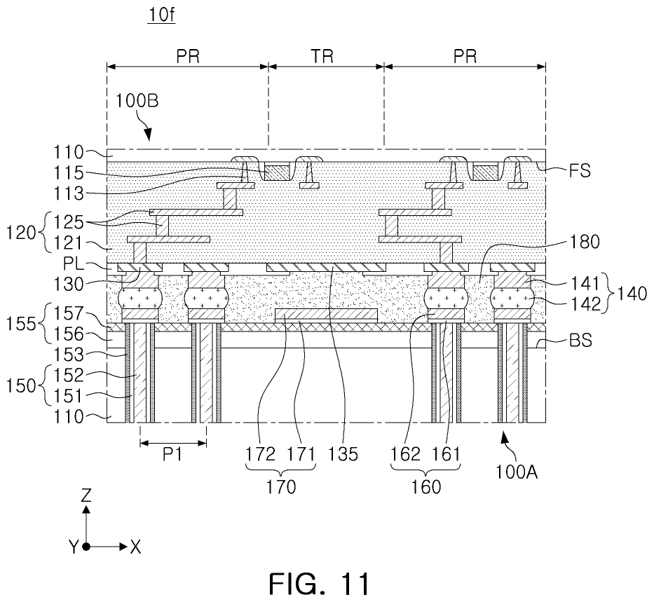

Referring to FIG. 11, the first semiconductor chip 100A of a semiconductor package 10f may include a rear structure 170 disposed on the back side BS. In an example embodiment, when viewed in cross-section, one rear structure 170 may be disposed in the test pad region TR. For example, the rear structure 170 may be disposed as illustrated in FIGS. 7 to 9. The horizontal width of the rear structures 170 may be 0.8 times to 1.2 times the horizontal width of the test pad 135.

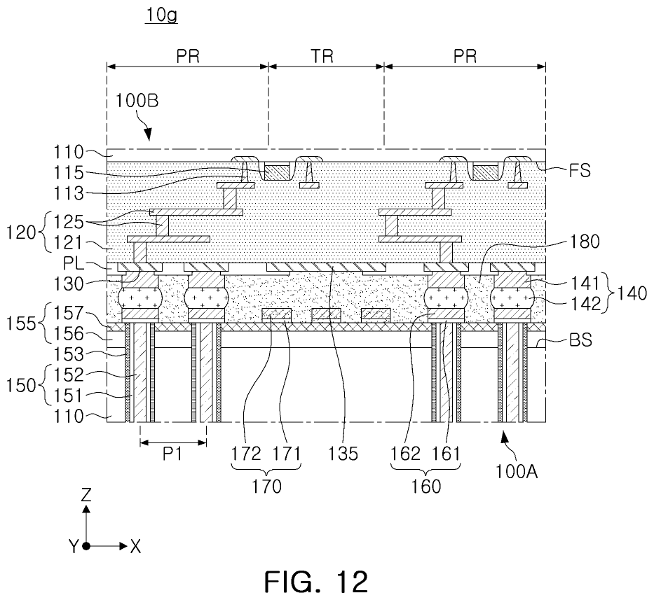

Referring to FIG. 12, the first semiconductor chip 100A of a semiconductor package 10g may include rear structures 170 disposed on the back side BS. In an example embodiment, when viewed in cross-section, three rear structures 170 may be disposed in the test pad region TR. For example, the rear structure 170 may be disposed as illustrated in FIG. 6. The horizontal width of the rear structure 170 may be less than the horizontal width of the rear pad 160.

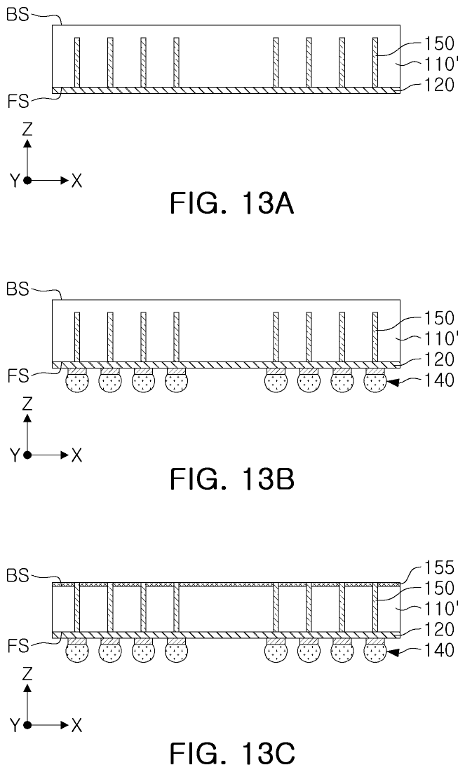

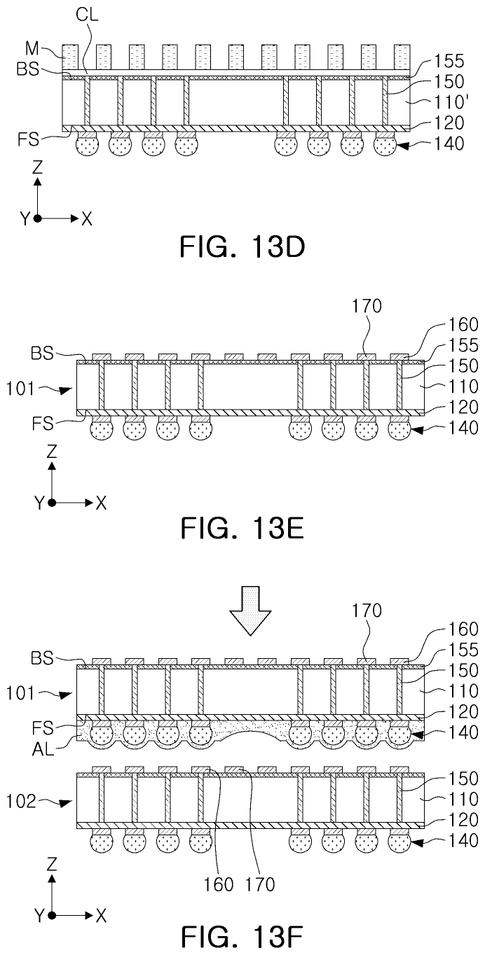

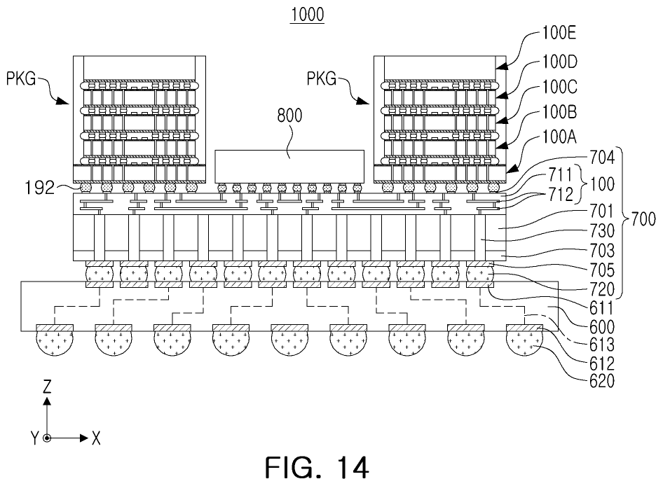

FIGS. 13A to 13F are cross-sectional views illustrating a major process of a method of manufacturing a semiconductor package according to example embodiments.

Referring to FIG. 13A, a preliminary substrate 110′ having the front side FS and the back side BS may be provided. The circuit layer 120 and the through-vias 150 may be formed on the front side FS of the preliminary substrate 110′. The through-vias 150 may be formed before or after the circuit layer 120 is formed. The through-vias 150 may extend vertically from the front side FS and may not completely pass through the preliminary substrate 110′.

Referring to FIG. 13B, the bump structures 140 may be formed on the front side FS of the preliminary substrate 110′. The bump structures 140 may be connected to the front pads 130 described herein with reference to FIG. 5. The bump structures 140 may be electrically connected to the circuit layer 120 through the front pads 130.

Referring to FIG. 13C, the back side BS of the preliminary substrate 110′ may be partially etched, and the rear protective layer 155 may be formed. For example, the back side BS may be partially removed to expose the through-vias 150, a protective material may be deposited to cover the back side BS and the through-vias 150, and the rear protective layer 155 may be formed by performing a planarization process.

Referring to FIG. 13D, a seed material layer CL may be formed on the rear protective layer 155, and a mask M may be formed on the seed material layer CL. The seed material layer CL may completely cover the rear protective layer 155, and the mask M may be patterned so that the seed material layer CL is partially exposed.

Referring to FIG. 13E, a plurality of rear pads 160 and rear structures 170 may be formed on the rear protective layer 155. For example, the metal layers 162 and 172 of the rear pads 160 and the rear structures 170 may be formed by performing a plating process using the seed material layer CL as a seed layer. Thereafter, the mask M may be removed, and the seed material layer CL covering the rear protective layer 155 may be partially removed to form seed layers 161 and 171 of the rear pads 160 and the rear structures 170. In an example embodiment, the rear structures 170 may be formed a separate process from the rear pads 160.

Thereafter, the substrate 110 may be formed by sawing the preliminary substrate 110′ along scribe lines (not shown), and an upper semiconductor chip 101 may be manufactured.

Referring to FIG. 13F, the upper semiconductor chip 101 may be mounted (or stacked) on a lower semiconductor chip 102. The lower semiconductor chip 102 may have a structure identical or similar to the upper semiconductor chip 101. For example, the upper semiconductor chip 101 and the lower semiconductor chip 102 may each correspond to one of the plurality of semiconductor chips 100A, 100B, 100C, 100D, and 100E illustrated in FIGS. 1 to 5.

In an example embodiment, the upper semiconductor chip 101 may be mounted on the lower semiconductor chip 102 by a thermal compression process. For example, an adhesive material layer AL covering the bump structures 140 may be formed on the front side FS of the upper semiconductor chip 101. Thereafter, the bump structures 140 may be bonded to the rear pads 160 of the lower semiconductor chip 102. The adhesive material layer AL may correspond to the adhesive layer 180 described herein. As illustrated in FIG. 1, during the thermal compression process, the adhesive material layer AL may move to the edge of the upper semiconductor chip 101 and a portion of the adhesive layer 180 may protrude from the side surface of the semiconductor chips.

As described herein with reference to FIG. 5, the front pad 130 and the bump structure 140 may not be disposed in the test pad region TR. Therefore, as illustrated in FIG. 13F, the distance between the first bump structure 140a and the second bump structure 140b may be greater than the pitch of the bump structures 140. In this case, a lower surface of the adhesive material layer AL may be concave between the first bump structure 140a and the second bump structure 140b, and the adhesive material layer AL may be formed to be relatively thin. Therefore, when the upper semiconductor chip 101 is mounted on the lower semiconductor chip 102 by a thermal compression process, the adhesive material layer AL may move to the center of the upper semiconductor chip 101 to fill space between the first bump structure 140a and the second bump structure 140b and there is a risk that the bump structures 140 may collapse.

However, according to example embodiments of the present inventive concept, the lower semiconductor chip 102 may include the rear structures 170 vertically overlapping the test pad 130 of the upper semiconductor chip 101 on an upper surface thereof. Therefore, during the thermal compression process, movement of the adhesive material layer AL between the first bump structure 140a and the second bump structure 140b may be prevented or reduced and the collapse of the bump structures 140 may be prevented or reduced. In addition, it is possible to prevent voids from occurring within the adhesive layer 180.

FIG. 14 is a vertical cross-sectional view of a semiconductor package according to example embodiments.

Referring to FIG. 14, the semiconductor package 1000 of an example embodiment may include a package substrate 600, an interposer substrate 700, and at least one package structure PKG. In addition, the semiconductor package 1000 may further include a logic chip or processor chip 800 disposed to be adjacent to the package structure PKG on the interposer substrate 700. The package structure PKG may have characteristics identical or similar to the semiconductor packages 10, 10a, 10b, 10c, 10d, 10e, 10f, and 10g described herein with reference to FIGS. 1 to 12.

The package substrate 600 may be a support substrate on which the interposer substrate 700, the logic chip 800, and the package structure PKG are mounted, and may be a substrate for a semiconductor package including a printed circuit board (PCB), a ceramic substrate, a glass substrate, a tape wring board, etc. The package substrate 600 may include a lower pad 612, an upper pad 611, and a redistribution circuit 613 electrically connecting the lower pad 612 and the upper pad 611. A body of the package substrate 600 may include different materials depending on the type of substrate. For example, if the package substrate 600 is a PCB, the package substrate 600 may be in the form in which an interconnection layer is additionally stacked on one surface or both surfaces of a body copper clad laminate or a copper clad laminate. The lower and upper pads 612 and 611 and the redistribution circuit 613 may form an electrical path connecting lower and upper surfaces of the package substrate 600. An external connection bump 620 connected to the lower pad 612 may be disposed on the lower surface of the package substrate 600. The external connection bump 620 may include, for example, a solder ball.

The interposer substrate 700 may include a substrate 701, a lower protective layer 703, a lower pad 705, an interconnection structure 710, a conductive bump 720, and a through-via 730. The package structure PKG and the processor chip 800 may be stacked on the package substrate 600 via the interposer substrate 700. The interposer substrate 700 may electrically connect the package structure PKG and the processor chip 800 to each other.

The substrate 701 may be formed of, for example, any one of silicon, organic, plastic, or glass substrates. When the substrate 701 is a silicon substrate, the interposer substrate 700 may be referred to as a silicon interposer. Unlike that illustrated in the drawing, when the substrate 701 is an organic substrate, the interposer substrate 700 may be referred to as a panel interposer.

The lower protective layer 703 may be disposed on a lower surface of the substrate 701, and the lower pad 705 may be disposed on the lower protective layer 703. The lower pad 705 may be connected to the through-via 730. The package structure PKG and the processor chip 800 may be electrically connected to the package substrate 600 through the conductive bumps 720 disposed on the lower pad 705.

The interconnection structure 710 may be disposed on the upper surface of the substrate 701 and may include an interlayer insulating layer 711 and a single-layer or multilayer interconnection 712. When the interconnection structure 710 has a multilayer interconnection structure, interconnection patterns of different layers may be connected to each other through contact vias. An upper pad 704 connected to the interconnection 712 may be disposed on the interconnection structure 710. The package structure PKG and the processor chip 800 may be connected to the upper pad 704 through a connection bump 192.

The through-via 730 may extend from an upper surface of the substrate 710 to a lower surface of the substrate 701 to pass through the substrate 701. In addition, the through-via 730 may extend into the interconnection structure 710 and be electrically connected to interconnections of the interconnection structure 710. If the substrate 701 is silicon, the through-via 730 may be referred to as a TSV. According to an example embodiment, the interposer substrate 700 may include only interconnection structures therein and may not include through-vias.

The interposer substrate 700 may be used to convert or transmit an input electrical signal between the package substrate 600 and the package structure PKG or the processor chip 800. Accordingly, the interposer substrate 700 may not include devices, such as active devices or passive devices. According to an example embodiment, the interconnection structure 710 may be disposed below the through-via 730.

The conductive bump 720 may be disposed on a lower surface of the interposer substrate 700 and electrically connected to the interconnection of the interconnection structure 710. The interposer substrate 700 may be mounted on the package substrate 600 through the conductive bump 720. The conductive bump 720 may be connected to the lower pad 705 through the interconnections of the interconnection structure 710 and the through-via 730. For example, some of the lower pads 705 used for power or grounding may be integrated and connected together to the conductive bumps 720, so that the number of lower pads 705 may be greater than the number of conductive bumps 720.

The logic chip or processor chip 800 may include, for example, a central processing unit (CPU), a graphics processing unit (GPU), a field programmable gate array (FPGA), a digital signal processor (DSP), a cryptographic processor, a microprocessor, a microcontroller, an analog-to-digital converter, or an application-specific integrated circuits (ASIC), etc.

According to example embodiments of the technical idea of the present inventive concept, in the structure in which the semiconductor chips are stacked, the rear structure is disposed on the upper surfaces of the semiconductor chips, thereby preventing voids from occurring within the adhesive layer between the semiconductor chips. In addition, it is possible to prevent bump structures from collapsing when the semiconductor chips are stacked.

While example embodiments have been illustrated and described herein, it will be apparent to those skilled in the art that modifications and variations could be made without departing from the scope of the present inventive concept as defined by the appended claims.

What is claimed is:

1. A semiconductor package comprising:
a first semiconductor chip including a substrate having a front side and a back side opposite each other, a rear protective layer on the back side of the substrate, a plurality of rear pads on the rear protective layer, and a rear conductive pattern between two rear pads of the plurality of rear pads;
a second semiconductor chip on the first semiconductor chip and including a first pad region, a second pad region, and a test pad region between the first pad region and the second pad region;
a plurality of chip interconnection terminals between the first semiconductor chip and the second semiconductor chip, wherein each chip interconnection terminal of the plurality of chip interconnection terminals is connected to a respective rear pad of the plurality of rear pads of the first semiconductor chip; and
an adhesive layer surrounding the plurality of chip interconnection terminals between the first semiconductor chip and the second semiconductor chip,
wherein
the first pad region includes a plurality of first front pads, the second pad region includes a plurality of second front pads, and the test pad region includes a test pad,
the pads of the plurality of first front pads are spaced apart from each other at a first pitch,
a minimum distance between the plurality of first front pads and the plurality of second front pads is greater than the first pitch, and
at least a portion of the rear conductive pattern vertically overlaps the test pad.

2. The semiconductor package of claim 1, wherein each first front pad from the plurality of first front pads is connected to a respective chip interconnection terminal from the plurality of chip interconnection terminals.
and each second front pad from the plurality of second front pads is connected to a respective chip interconnection terminal from the plurality of chip interconnection terminals.

3. The semiconductor package of claim 1, wherein
the rear conductive pattern is not electrically connected to any chip interconnection terminals of the semiconductor package, and
the test pad is not electrically connected to any chip interconnection terminals of the semiconductor package.

4. The semiconductor package of claim 1, wherein a lower surface of the test pad is in contact with the adhesive layer.

5. The semiconductor package of claim 1, wherein an upper surface of the rear conductive pattern is in contact with the adhesive layer.

6. The semiconductor package of claim 1, wherein the test pad is not electrically connected to the rear conductive pattern.

7. The semiconductor package of claim 1, wherein
the first semiconductor chip further includes a circuit layer on the front side,
at least one rear pad of the plurality of rear pads is electrically connected to the circuit layer, and
the rear conductive pattern is not electrically connected to the circuit layer.

8. The semiconductor package of claim 1, wherein a thickness of the rear conductive pattern is equal to a thickness of each rear pad of the plurality of rear pads.

9. The semiconductor package of claim 1, wherein the rear conductive pattern includes a seed layer in contact with the rear protective layer and a metal layer on the seed layer.

10. The semiconductor package of claim 1, wherein a horizontal width of the rear conductive pattern is equal to a horizontal width of each rear pad of the plurality of rear pads.

11. The semiconductor package of claim 1, wherein
the rear conductive pattern is a first rear conductive pattern, and further comprises a second rear conductive pattern spaced apart from the first rear conductive pattern at a second pitch, and
the second pitch is equal to the first pitch.

12. The semiconductor package of claim 1, wherein a thickness of the rear conductive pattern is greater than a thickness of each rear pad of the plurality of rear pads.

13. The semiconductor package of claim 12, wherein the thickness of the at rear conductive pattern is 0.5 times to 0.75 times a thickness of the adhesive layer.

14. The semiconductor package of claim 1, wherein
the rear conductive pattern is a first rear conductive pattern, and further comprises a second rear conductive pattern spaced apart from the first rear conductive pattern at a second pitch, and
the second pitch is less than the first pitch.

15. The semiconductor package of claim 1, wherein a horizontal width of the rear conductive pattern is 0.8 times to 1.2 times a horizontal width of the test pad.

16. The semiconductor package of claim 1, wherein the rear conductive pattern includes a same material as the plurality of rear pads.

17. A semiconductor package comprising:
a first semiconductor chip including a substrate having a front side and a back side opposite each other, a rear protective layer on the back side of the substrate, a plurality of rear pads on the rear protective layer, and a rear conductive pattern between two rear pads of the plurality of rear pads;
a second semiconductor chip on the first semiconductor chip, wherein the second semiconductor chip includes a plurality of front pads electrically connected to the plurality of rear pads and a test pad between two front pads of the plurality of front pads;
a plurality of chip interconnection terminals, each chip interconnection terminal being between a respective rear pad of the plurality of rear pads of the first semiconductor chip, and a respective front pad of the plurality of front pads of the second semiconductor chip; and
an adhesive layer surrounding the plurality of chip interconnection terminals between the first semiconductor chip and the second semiconductor chip,
wherein
the plurality of chip interconnection terminals includes a first chip interconnection terminal, a second chip interconnection terminal, and a third chip interconnection terminal spaced apart from each other in a first horizontal direction,
a first center of the first chip interconnection terminal and a second center of the second chip interconnection terminal are spaced apart from each other by a first distance in the first horizontal direction and the second center of the second chip interconnection terminal is spaced apart from a third center of the third chip interconnection terminal by a second distance, greater than the first distance, in the first horizontal direction,
the test pad is between the second chip interconnection terminal and the third chip interconnection terminal, and
at least a portion of the rear conductive pattern vertically overlaps the test pad.

18. The semiconductor package of claim 17, wherein
the second semiconductor chip further includes a front protective layer covering the plurality of front pads and the test pad,
the adhesive layer includes a first portion between the rear protective layer and the front protective layer and a second portion between the rear conductive pattern and the test pad, and
a first thickness of the first portion of the adhesive layer is greater than a second thickness of the second portion of the adhesive layer.

19. The semiconductor package of claim 17, wherein
the first semiconductor chip further includes a plurality of through-vias extending from the front side to the back side,
the plurality of rear pads vertically overlaps the plurality of through-vias, and
the rear conductive pattern is spaced apart from the plurality of through-vias.

20. A semiconductor package comprising:
a plurality of semiconductor chips stacked in a vertical direction;
a plurality of bump terminals electrically connecting the plurality of semiconductor chips between the plurality of semiconductor chips;
a plurality of adhesive layers surrounding the plurality of bump terminals between the plurality of semiconductor chips; and
an encapsulant covering the plurality of semiconductor chips and the plurality of adhesive layers,
wherein the plurality of semiconductor chips include:
a first semiconductor chip including a substrate having a front side and a back side opposite each other, a rear protective layer on the back side of the substrate, a plurality of rear pads on the rear protective layer, and a rear conductive pattern between two rear pads of the plurality of rear pads; and
a second semiconductor chip on the first semiconductor chip and including a first pad region, a second pad region, and a test pad region between the first pad region and the second pad region;
wherein
the first pad region includes a plurality of first front pads, the second pad region includes a plurality of second front pads, and the test pad region includes a test pad,
the pads of the plurality of first front pads are spaced apart from each other at a first pitch,
a minimum distance between the plurality of first front pads and the plurality of second front pads is greater than the first pitch, and
at least a portion of the rear conductive pattern vertically overlaps the test pad.
